(19) United States
(12) Patent Application Publication
(10) Pub. No.: US 2025/0232904 A1
(43) Pub. Date: Jul. 17, 2025

(54) SPIRAL INDUCTORS AND ANTENNAS THAT ARE INTEGRATED IN ELECTRONIC ASSEMBLIES

(71) Applicant: Super Micro Computer, Inc., San Jose, CA (US)

(72) Inventors: Manhtien V. PHAN, San Jose, CA (US); Chih-Hao LEE, New Taipei City (TW)

(21) Appl. No.: 18/413,981

(22) Filed: Jan. 16, 2024

(51) Int. Cl. H01F 17/00; H05K 1/18

(52) U.S. Cl. CPC H01F 17/0033; H05K 1/184

(57) ABSTRACT

Disclosed is an electronic assembly with an integrated spiral inductor. The electronic assembly includes a substrate that has through holes, which are disposed along a side edge of the substrate. A wire of the spiral inductor is wound several turns, in spiral fashion, around the side edge by way of the through holes. A magnetic core can be included in the spiral inductor for increased inductance. The electronic assembly can have an additional substrate, and the spiral inductor spirals around side edges of the substrates by way of through holes of the substrates.

### TECHNICAL FIELD

The present disclosure is directed to inductors and antennas.

### BACKGROUND

Inductors are well-known components employed in many electronic devices. An inductor may be employed as a discrete inductor or as an antenna of an electrical circuit. Due to their bulky structure, which comprises a wire that is wound a plurality of turns, inductors are usually taller and physically larger than most other components on an electronic assembly of an electronic device. The continually shrinking form factor of today's electronic devices requires inductors that do not take a lot of space on the substrate of the electronic assembly.

### BRIEF SUMMARY

In one embodiment, an electronic assembly comprises a substrate, an inductor, and an electrical circuit. The substrate comprises a plurality of through holes that each goes through the substrate, the plurality of through holes of the substrate is disposed along a side edge of the substrate. The inductor comprises a wire that is wound in spiral fashion a plurality of turns around the side edge by way of the plurality of through holes. The inductor is electrically connected to the electrical circuit. A magnetic core may be disposed within the inductor. The inductor may be used as a discrete inductor or as an antenna.

In another embodiment, an electronic assembly comprises a first substrate, a second substrate, and an inductor. The first substrate has a plurality of through holes that go through the first substrate, the plurality of through holes of the first substrate being disposed along a side edge of the first substrate. The second substrate has a plurality of through holes that go through the second substrate, the plurality of through holes of the second substrate being disposed along a side edge of the second substrate. The inductor comprises a wire that is wound in spiral fashion a plurality of turns around the side edge of the first substrate and the side edge of the second substrate by way of the plurality of through holes of the first substrate and the plurality of through holes of the second substrate. A magnetic material may be disposed within the inductor. The inductor may be used as a discrete inductor or as an antenna.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIGS. 1-3 show various views of a spiral inductor, in accordance with an embodiment of the present invention.

FIGS. 4-7 show various views of an electronic assembly, in accordance with an embodiment of the present invention.

FIG. 8 shows a plot of inductance versus frequency of a simulation of the spiral inductor of FIG. 1 in the electronic assembly of FIGS. 4-7.

FIGS. 9-11 show various views of an electronic assembly with a magnetic core, in accordance with another embodiment of the present invention.

FIG. 12 shows a plot of inductance versus frequency of a simulation of the spiral inductor of FIG. 1 in the electronic assembly of FIGS. 9-11.

FIGS. 13-16 show various views of an electronic assembly with stacked substrates, in accordance with yet another embodiment of the present invention.

FIGS. 17-19 show various views of an electronic assembly with stacked substrates and a magnetic core, in accordance with yet another embodiment of the present invention.

FIGS. 20-23 show various views of an electronic assembly with an electrical insulator layer between stacked substrates, in accordance with yet another embodiment of the present invention.

FIGS. 24-27 show various views of an electronic assembly with side-by-side substrates, in accordance with yet another embodiment of the present invention.

FIG. 28 shows a plot of inductance versus frequency of a simulation of the spiral inductor of FIG. 1 in the electronic assembly of FIGS. 24-27.

FIGS. 29-32 show various views of an electronic assembly with side-by-side substrates and a magnetic core, in accordance with yet another embodiment of the present invention.

FIG. 33 shows a plot of inductance versus frequency of a simulation of the spiral inductor of FIG. 1 in the electronic assembly of FIGS. 29-32.

FIG. 34 shows a magnetic field simulation of the spiral inductor of FIG. 1, in accordance with an embodiment of the present invention.

FIG. 35 shows a side view of the spiral inductor of FIG. 1 with a magnetic core, in accordance with an embodiment of the present invention.

FIG. 36 shows a plot of inductance versus frequency of a simulation of the spiral inductor of FIG. 35, in accordance with an embodiment of the present invention.

### DETAILED DESCRIPTION

In the present disclosure, numerous specific details are provided, such as examples of components, structures, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

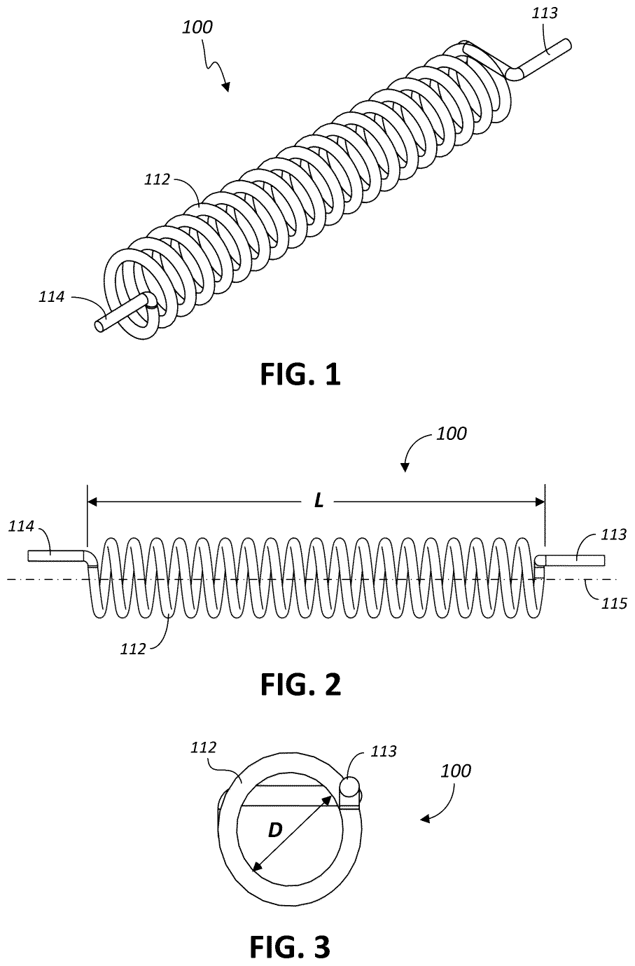

FIG. 1 shows a perspective view of a spiral inductor 100, in accordance with an embodiment of the present invention. The spiral inductor 100 has a spiral structure in that the wire 112 is wound in spiral fashion a plurality of turns around a core region, which is air in the example of FIG. 1. The spiral inductor 100 comprises a single piece of wire 112 that is continuous from a first end 113 to a second end 114. The ends 113 and 114 are shown as straight extensions to facilitate connection of the wire 112 to an electrical circuit. The spiral inductor 100 may comprise an electrical conductor that is coated with an electrically insulating material, such as a copper wire that is coated with enamel. The diameter of the wire 112 (i.e., gauge) depends on the target inductance and/or current carrying capacity. The inductance of the spiral inductor 100 may be adjusted by varying the physical dimensions of the spiral inductor 100, varying the number of tuns of the wire 112, varying the diameter of the wire 112, adding a magnetic core within the spiral inductor 100, etc. and may be confirmed or determined using simulation software or by testing/measurement.

FIGS. 2 and 3 show a side view and a front view, respectively, of the spiral inductor 100, in accordance with an embodiment of the present invention. The spiral wound portion of the spiral inductor 100 has a length L and an inside diameter D. It is to be noted that the spiral wound portion does not necessarily have to form a circle, e.g., could have an oval shape. The ends 113 and 114 of the wire 112 are shown as extending on the same side of an imaginary plane (not shown) on a long axis 115 of the spiral wound portion. As can be appreciated, this is not necessarily the case. The ends 113 and 114 may extend on the same side or opposite sides of the plane. For example, the ends 113 may be on the same side or opposite sides of a substrate of an electronic assembly.

The spiral inductor 100 may be incorporated into an electronic assembly as a discrete inductor or as antenna. Generally, an electronic assembly includes a plurality of electronic components that are mounted on a substrate, such as a printed circuit board (PCB). With some exceptions, electronic components are not shown in the following figures for clarity of illustration. Also, only the portion of the substrate that has the spiral inductor 100 is shown for clarity of illustration.

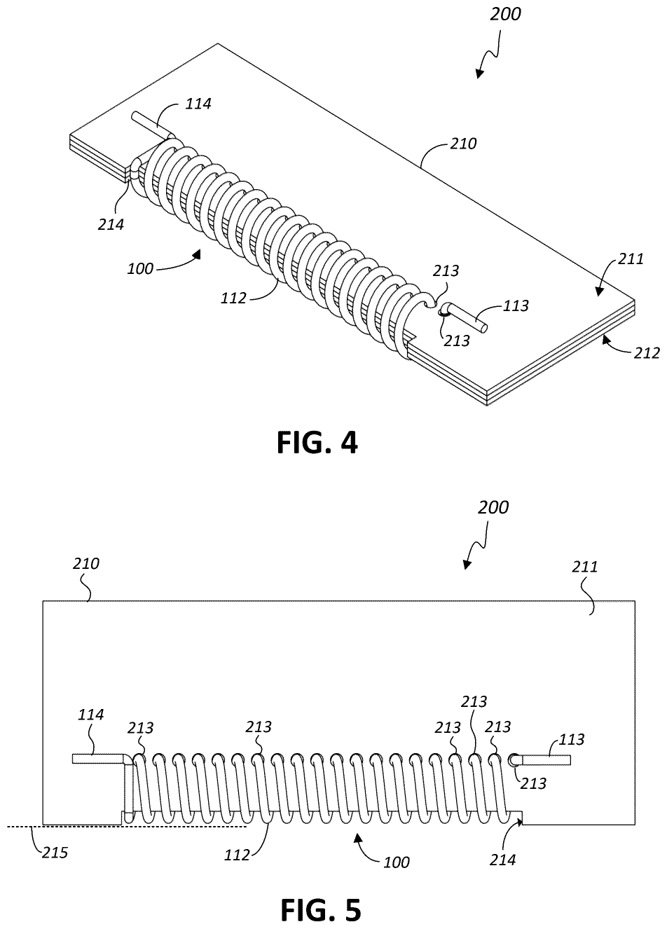

FIG. 4 shows a perspective view of an electronic assembly 200, in accordance with an embodiment of the present invention. The electronic assembly 200 comprises a substrate 210 and a plurality of electronic components including the spiral inductor 100. The substrate 210 comprises a PCB with a first outermost surface 211 and an opposing second outermost surface 212. The substrate 210 includes a plurality of through holes 213 that are disposed along a side edge of the substrate 210. Each through hole 213 goes all the way through the substrate 210, i.e., all the way through the outermost surfaces 211 and 212. The spiral inductor 100 winds a plurality of turns around the side edge, all the way through the substrate 210, by way of the through holes 213. In the example of FIG. 4, the first end 113 and the second end 114 of the wire 112 are both over the outermost surface 211. Generally, the first end 113 and the second end 114 may be over the same outermost surface or over different outermost surfaces of the substrate 210.

The spiral inductor 100 is disposed such that the side edge is confined within the spiral inductor 100. This results in the spiral inductor 100 extending beyond the side edge that is within the spiral inductor 100. In the example of FIG. 4, the side edge of the substrate 210 has an edge cutout 214. The spiral inductor 100 is disposed within the edge cutout 214 to minimize the portion of the spiral inductor 100 that extends beyond the perimeter of the substrate 210, thereby maintaining a relatively small profile.

FIG. 5 shows a top view of the electronic assembly 200, in accordance with an embodiment of the present invention. FIG. 5 shows the substrate 210 with its outermost surface 211 facing up on the page. The wire 112 of the spiral inductor 100 spirals through the substrate 210 by way of the through holes 213 that are disposed along the side edge that has the edge cutout 214. In the example of FIG. 5, the spiral inductor 100 does not extend beyond the perimeter (see imaginary line 215) of the substrate 210. In other embodiments, the spiral inductor 100 extends beyond the perimeter.

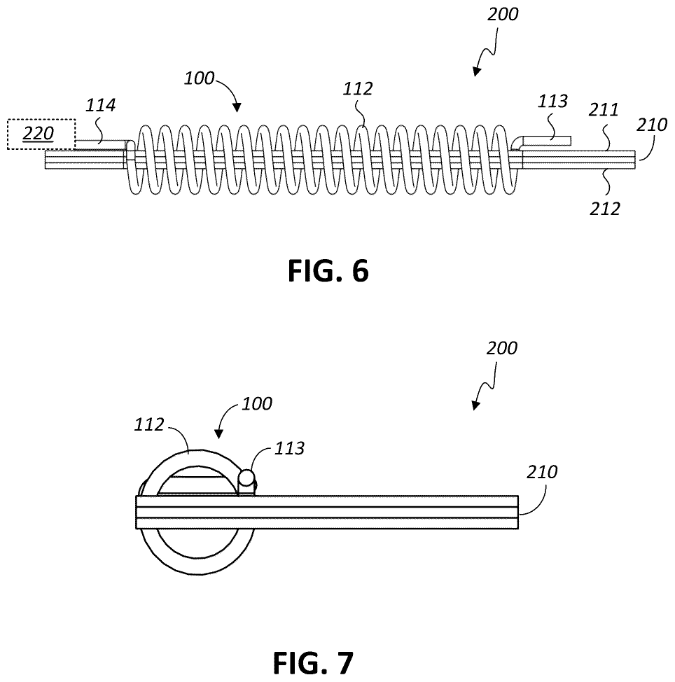

FIG. 6 shows a side view of the electronic assembly 200, in accordance with an embodiment of the present invention. FIG. 6 shows a schematic representation of an electrical circuit 220, which comprises a plurality of electronic components (e.g., resistors, capacitors, other inductors, integrated circuit (IC) chips) that are electrically connected to the spiral inductor 100. The electrical circuit 220 may be mounted on the outermost surface 211 as shown or on the outermost surface 212, and may be electrically connected to the second end 114 as shown, to the first end 113, or to both the ends 113 and 114.

FIG. 7 shows a front view of the electronic assembly 200, in accordance with an embodiment of the present invention. The substrate 210 is shown with the first end 113 of the wire 112 of the spiral inductor 100 facing toward the viewer for reference.

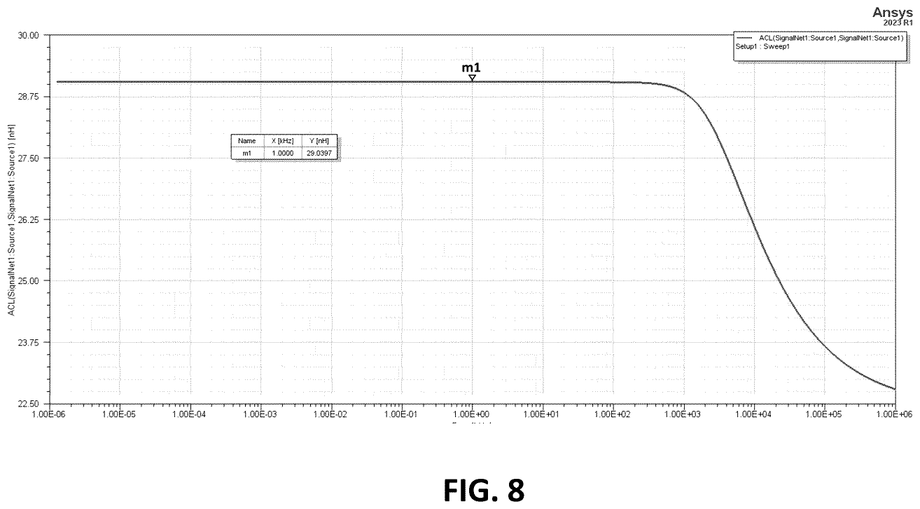

FIG. 8 shows a plot of inductance versus frequency of a simulation of the spiral inductor 100 in the electronic assembly 200, in accordance with an embodiment of the present invention. The simulation was performed using the ANSYS 2023 R1 simulation software, which is commercially-available from ANSYS, Inc. In the simulation of FIG. 8, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils. The substrate 210 is a conventional PCB, which does not appreciably affect the inductance of the spiral inductor 100. In the example of FIG. 8, the vertical axis represents inductance in nH and the horizontal axis represents frequency in kHz. For reference, at the point ml in FIG. 8, the spiral inductor 100 in the simulation has an inductance of around 29 nH at around 1 kHz.

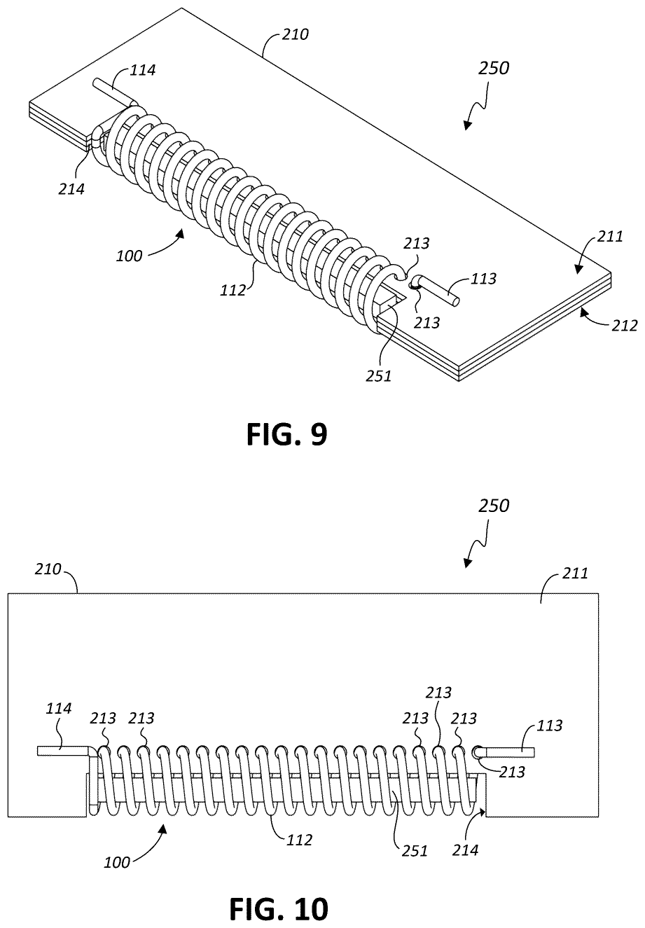

FIG. 9 shows a perspective view of an electronic assembly 250, in accordance with an embodiment of the present invention. The electronic assembly 250 is essentially the same as the electronic assembly 200 (shown in FIGS. 4-7) except for the addition of a magnetic core 251 that is disposed within the spiral inductor 100. That is, whereas the spiral inductor 100 has an air core in the electronic assembly 200, the spiral inductor 100 has a magnetic core 251 in the electronic assembly 250. The wire 112 is wound a plurality of turns, in spiral fashion, around the side edge of the substrate 210 and the magnetic core 251 by way of the through holes 213. The edge cutout 214 is deeper in the electronic assembly 250 to accommodate the magnetic core 251. The electronic assemblies 200 and 250 are otherwise essentially the same.

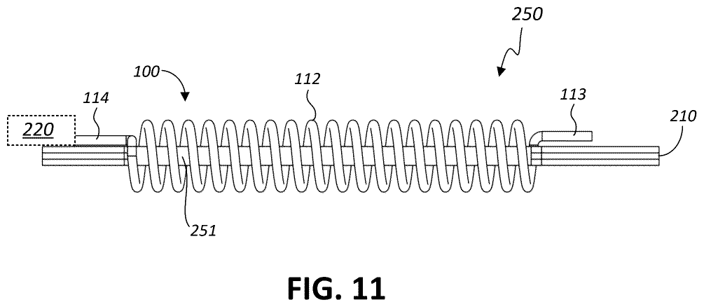

FIGS. 10 and 11 show a top view and a side view, respectively, of the electronic assembly 250. The magnetic core 251 may comprise a magnetic material commonly used in inductors, such as iron powder and ferrites. The magnetic core 251 may be disposed within the spiral inductor 100 by attaching it to opposing edges of the substrate 210 in the edge cutout 214, by form fitting the magnetic core 251 into the inside diameter of the spiral inductor 100, or some other way depending on implementation particulars. The magnetic core 251 may have a rectangular box shape as shown, cylindrical shape, two-half cylindrical shapes, or other shape. Changing the shape, size, and/or material of the magnetic core 251 allows for adjustment of the inductance of the spiral inductor 100 in the electronic assembly 250.

The numbered components of the electronic assembly 250 in FIGS. 9-11, except for the magnetic core 251, are as described in previous figures with the same reference numbers.

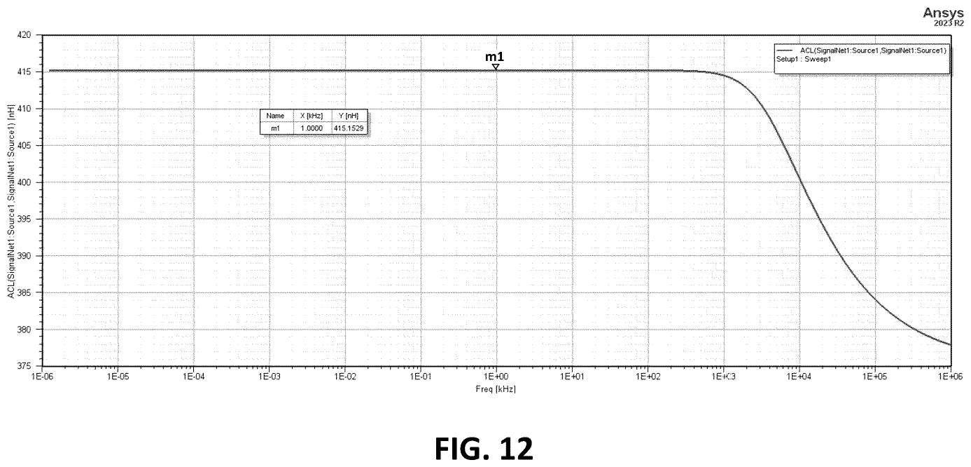

FIG. 12 shows a plot of inductance versus frequency of a simulation of the spiral inductor 100 in the electronic assembly 250, in accordance with an embodiment of the present invention. The simulation was performed using the ANSYS 2023 R1 simulation software. In the simulation of FIG. 12, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils; and the magnetic core 251 is a ferrite core. The substrate 210 is a conventional PCB, which does not appreciably affect the inductance of the spiral inductor 100. In FIG. 12, the vertical axis represents inductance in nH and the horizontal axis represents frequency in kHz. For reference, at the point m1 in FIG. 12, the spiral inductor 100 in the simulation has an inductance of around 415.1 nH at around 1 kHz. The increased inductance relative to the spiral inductor 100 in the electronic assembly 200 (sec FIG. 8) is attributed to the addition of the magnetic core 251 in the spiral inductor 100.

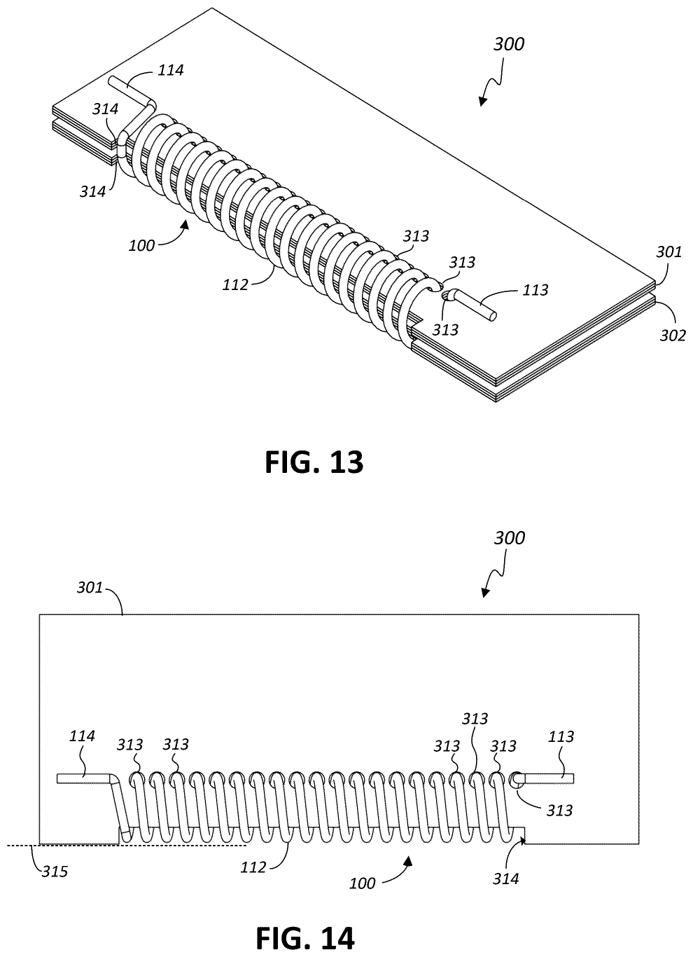

FIG. 13 shows a perspective view of an electronic assembly 300, in accordance with an embodiment of the present invention. The electronic assembly 300 comprises a substrate 301, a substrate 302, and a plurality of electronic components that includes the spiral inductor 100. Each of the substrates 301 and 302 may comprise a PCB with a plurality of electronic components mounted thereon.

In the electronic assembly 300, the substrates 301 and 302 are in a stacked configuration in that one is over the other. The spiral inductor 100 prevents the substrates 301 and 302 from being separated, but the substrates 301 and 302 are not fixedly attached together. Movement of the substrates 301 and 302 may be limited by the inside diameter of the spiral inductor 100, the diameter of the wire 112 relative to the through holes 313 of the substrates 301 and 302, and the shape and dimensions of the substrates 301 and 302.

The substrates 301 and 302 have the same shape and dimensions in the example of FIG. 13. Each of the substrates 301 and 302 includes a plurality of through holes 313 that are correspondingly aligned and disposed along corresponding side edges, with each through hole 313 going all the way through the corresponding substrate. The spiral inductor 100 winds a plurality of turns around the side edges of the substrates 301 and 302, in spiral fashion, all the way through the substrates 301 and 302 by way of corresponding through holes 313. In the example of FIG. 13, the first end 113 and the second end 114 of the wire 112 are both over an outermost surface of the substrate 301 for illustration purposes.

The spiral inductor 100 is disposed such that the side edges of the substrates 301 and 302 are confined within the spiral inductor 100. This results in the spiral inductor 100 extending beyond the side edges that are within the spiral inductor 100. In the example of FIG. 13, each of the substrates 301 and 302 has an edge cutout 314. The spiral inductor 100 is disposed within the edge cutouts 314 to minimize the portion of the spiral inductor 100 that extends beyond the perimeters of the substrates 301 and 302.

FIG. 14 shows a top view of the electronic assembly 300, in accordance with an embodiment of the present invention. FIG. 14 shows an outermost surface of the substrate 301, but FIG. 14 equally applies to the substrate 302. The wire 112 of the spiral inductor 100 spirals through the substrate 301 and the substrate 302 (not shown; under the substrate 301) by way of the through holes 313, which are along the side edges that have the edge cutouts 314. In the example of FIG. 14, the spiral inductor 100 does not extend beyond the perimeters (see imaginary line 315) of the substrates 301 and 302. In other embodiments, the spiral inductor 100 extends beyond the perimeters.

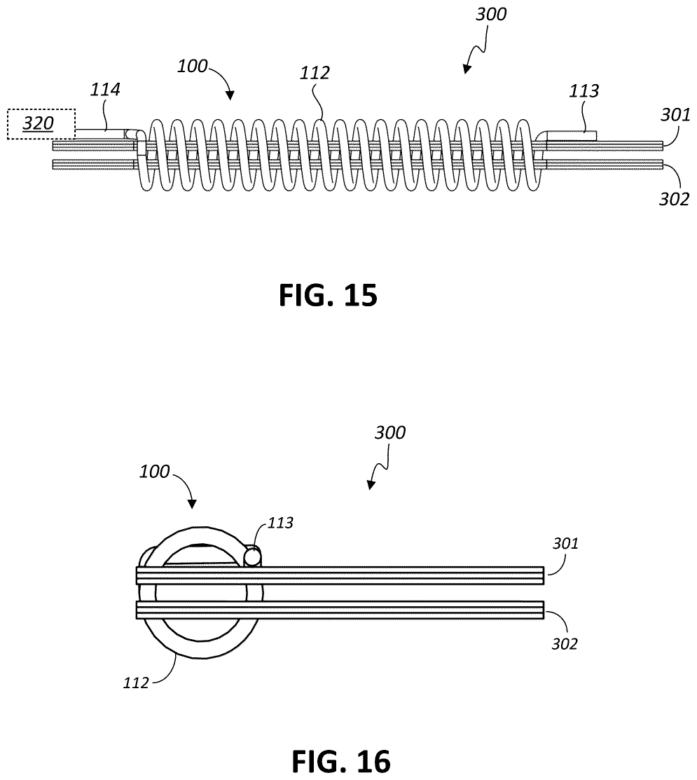

FIG. 15 shows a side view of the electronic assembly 300, in accordance with an embodiment of the present invention. FIG. 15 shows a schematic representation of an electrical circuit 320, which comprises a plurality of electronic components (e.g., resistors, capacitors, other inductors, IC chips) that are electrically connected to the spiral inductor 100. The electrical circuit 320 may be mounted on an outermost surface of the substrate 301 as shown or on an outermost surface of the substrate 302, and may be electrically connected to the second end 114 as shown, to the first end 113, or to both the ends 113 and 114.

FIG. 16 shows a front view of the electronic assembly 300, in accordance with an embodiment of the present invention. The substrates 301 and 302 are shown with the first end 113 of the wire 112 of the spiral inductor 100 facing toward the viewer for reference.

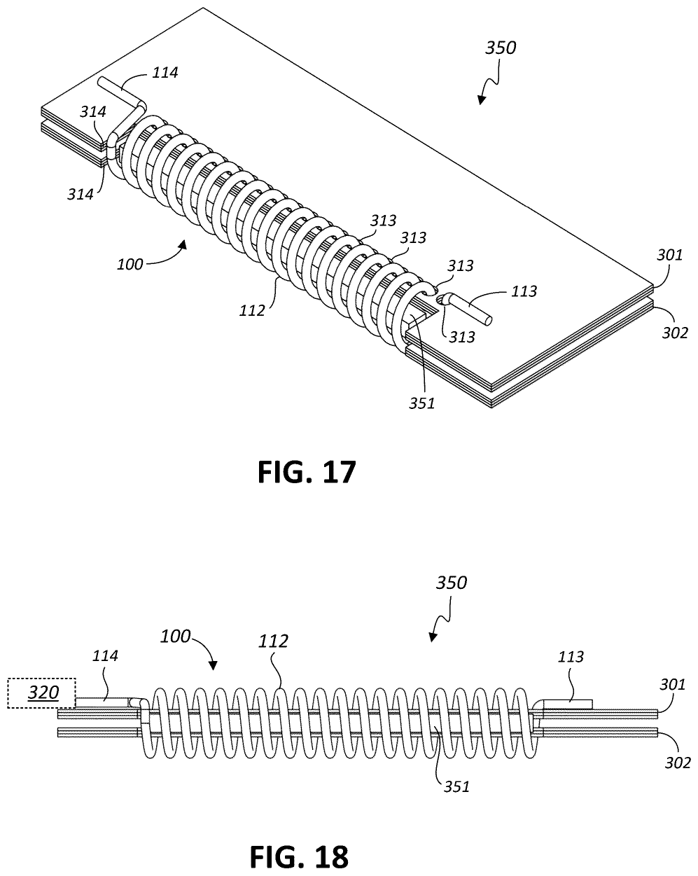

FIG. 17 shows a perspective view of an electronic assembly 350, in accordance with an embodiment of the present invention. The electronic assembly 350 is essentially the same as the electronic assembly 300 (shown in FIGS. 13-16) except for the addition of a magnetic core 351 that is disposed within the spiral inductor 100. That is, whereas the spiral inductor 100 has an air core in the electronic assembly 300, the spiral inductor 100 has a magnetic core 351 in the electronic assembly 350. The wire 112 is wound a plurality of turns, in spiral fashion, around the magnetic core 351 and the side edges of the substrates 301 and 302 by way of the through holes 313. The edge cutouts 314 are deeper in the electronic assembly 350 to accommodate the magnetic core 351. The electronic assemblies 300 and 350 are otherwise essentially the same.

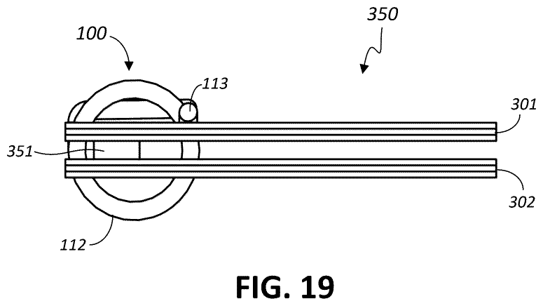

FIGS. 18 and 19 show a side view and a front view, respectively, of the electronic assembly 350, in accordance with an embodiment of the present invention. The magnetic core 351 may comprise a magnetic material commonly used in inductors, such as iron powder and ferrites. The magnetic core 351 may be disposed within the spiral inductor 100 by form fitting the magnetic core 351 into the inside diameter of the spiral inductor 100, or some other way depending on implementation particulars. The magnetic core 351 may have a rectangular box shape as shown, cylindrical shape, two-half cylindrical shapes, or other shape. Changing the shape, size, and/or material of the magnetic core 351 allows for adjustment of the inductance of the spiral inductor 100 in the electronic assembly 350.

The numbered components of the electronic assembly 350 in FIGS. 17-19, except for the magnetic core 351, are as described in previous figures with the same reference numbers.

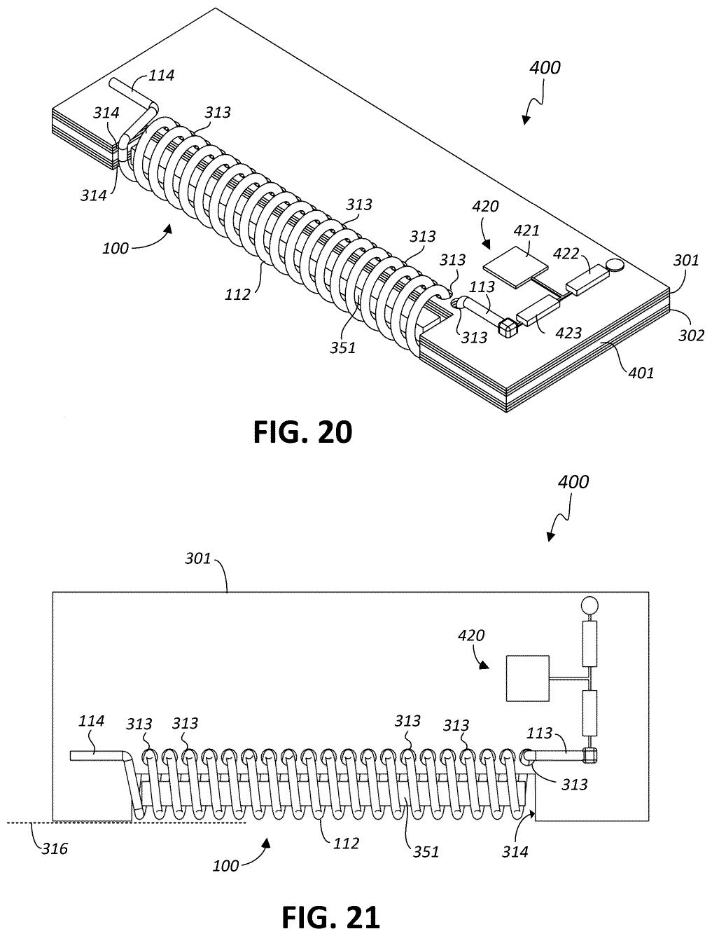

FIG. 20 shows a perspective view of an electronic assembly 400, in accordance with an embodiment of the present invention. The electronic assembly 400 is essentially the same as the electronic assembly 350 (shown in FIGS. 17-19) except for the addition of an electrical insulator layer 401 between the substrates 301 and 302. The substrates 301 and 302 are fixedly attached to the insulator layer 401. The insulator layer 401 includes a plurality of through holes 313 that line up with the through holes 313 of the substrates 301 and 302. The wire 112 is wound a plurality of turns, in spiral fashion, around the magnetic core 351 and the side edges of the substrate 301, the insulator layer 401, and the substrate 302 by way of the through holes 313. The electronic assemblies 400 and 350 are otherwise essentially the same.

The substrate configuration of the electronic assembly 400 is suitable in applications where it is not desirable for the substrates 301 and 302 to touch or swing in place.

In the embodiment where the substrates 301 and 302 are PCBs, the insulator layer 401 may comprise an electrically insulating material that is commonly-used with PCBs, and may be fixedly attached to the substrates 301 and 302 using a process that is commonly-used in the PCB industry. An electrical circuit 420 comprising a plurality of electronic components including electronic components 421 (e.g., an IC chip), 422 (e.g., a resistor), and 423 (e.g., a capacitor) are shown as mounted on an outermost surface of the substrate 301 for illustration purposes.

The substrate 301, the substrate 302, and the insulator layer 401 have the same shape and dimensions in the example of FIG. 20. Each of the substrate 301, the substrate 302, and the insulator layer 401 includes a plurality of through holes 313 that are correspondingly aligned. The spiral inductor 100 winds a plurality of turns around the side edge of the substrate 301, the side edge of the insulator layer 401, and the side edge of the substrate 302, in spiral fashion, all the way through the substrate 301, the insulator layer 401, and the substrate 302 by way of corresponding through holes 313. In the example of FIG. 20, the first end 113 and the second end 114 of the wire 112 are both over an outermost surface of the substrate 301 for illustration purposes.

The spiral inductor 100 is disposed such that the side edges of the substrate 301, the insulator layer 401, and the substrate 302 are confined within the spiral inductor 100. This results in the spiral inductor 100 extending beyond side edges that are within the spiral inductor 100. In the example of FIG. 20, each of the substrate 301, the insulator layer 401, and the substrate 302 has an edge cutout 314. The spiral inductor 100 is disposed within the edge cutout 314 to minimize the portion of the spiral inductor 100 that extends beyond the perimeters of the substrate 301, the insulator layer 401, and the substrate 302.

FIG. 21 shows a top view of the electronic assembly 400, in accordance with an embodiment of the present invention. FIG. 21 shows an outermost surface of the substrate 301, but FIG. 21 equally applies to the substrate 302. The wire 112 of the spiral inductor 100 spirals through the substrate 301, the insulator layer 401 (not shown), and the substrate 302 (not shown) by way of the through holes 313, which are along the side edges that have the edge cutouts 314. In the example of FIG. 21, the spiral inductor 100 does not extend beyond the perimeters (see imaginary line 316) of the substrate 301, the insulator layer 401, and the substrate 302. In other embodiments, the spiral inductor 100 extends beyond the perimeters.

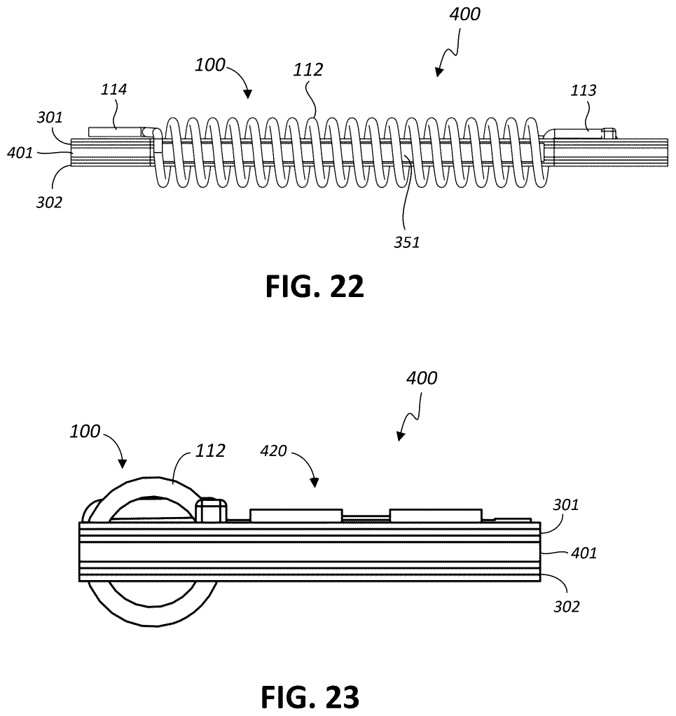

FIGS. 22 and 23 show a side view and a front view, respectively, of the electronic assembly 400, in accordance with an embodiment of the present invention. The numbered components of the electronic assembly 400 in FIGS. 20-23, except for the insulator layer 401, are as described in previous figures with the same reference numbers.

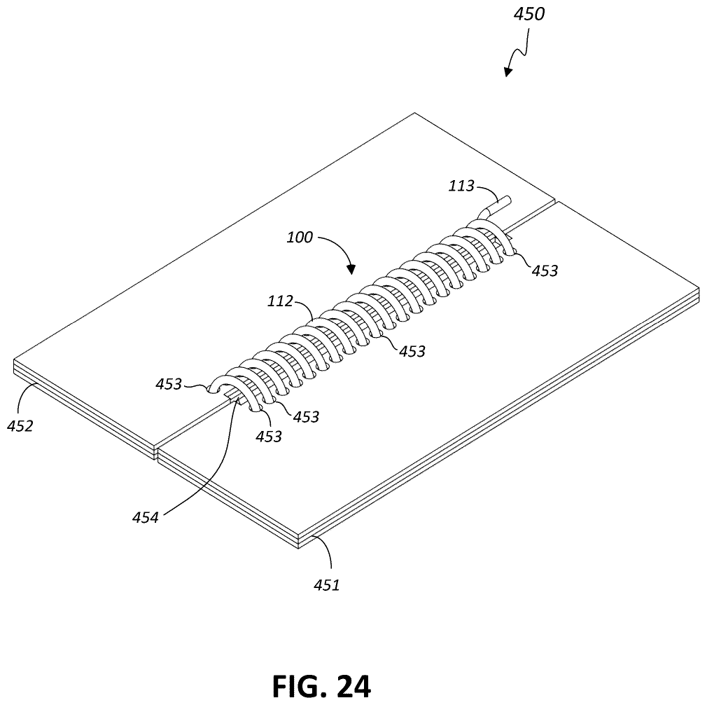

FIG. 24 shows a perspective view of an electronic assembly 450, in accordance with an embodiment of the present invention. The electronic assembly 450 comprises a substrate 451, a substrate 452, and a plurality of electronic components that includes the spiral inductor 100. Each of the substrates 451 and 452 may comprise a PCB with a plurality of electronic components mounted thereon. Electronic components may be mounted on one or more surfaces of the substrates 451 and 452.

In the electronic assembly 450, the spiral inductor 100 prevents the substrates 451 and 452 from being separated, but the substrates 451 and 452 are not fixedly attached together. The substrates 451 and 452 are in a side-by-side configuration, i.e., the substrates 451 and 452 are beside one another with facing side edges. Movement of the substrates 451 and 452 may be limited by the inside diameter of the spiral inductor 100, the diameter of the wire 112 relative to the through holes 453 of the substrates 451 and 452, and the dimensions and shape of the substrates 451 and 452.

The substrates 451 and 452 have the same shape and dimensions in the example of FIG. 24. Each of the substrates 451 and 452 includes a plurality of through holes 453, with each through hole 453 going all the way through the corresponding substrate. The spiral inductor 100 winds a plurality of turns around the side edges of the substrates 451 and 452, in spiral fashion, all the way through the substrates 451 and 452 by way of corresponding through holes 453. In the example of FIG. 24, the first end 113 of the wire 112 is over an outermost surface of the substrate 452 for illustration purposes.

The spiral inductor 100 is disposed such that the side edges of the substrates 451 and 452 are confined within the spiral inductor 100. In the example of FIG. 24, each of the substrates 451 and 452 has an edge cutout that together forms a channel 454 within the spiral inductor 100. The spiral inductor 100 has an air core in the electronic assembly 450 in that the channel 454 is empty. As will be more apparent below, a magnetic core may be disposed in the channel 454 to increase the inductance of the spiral inductor 100.

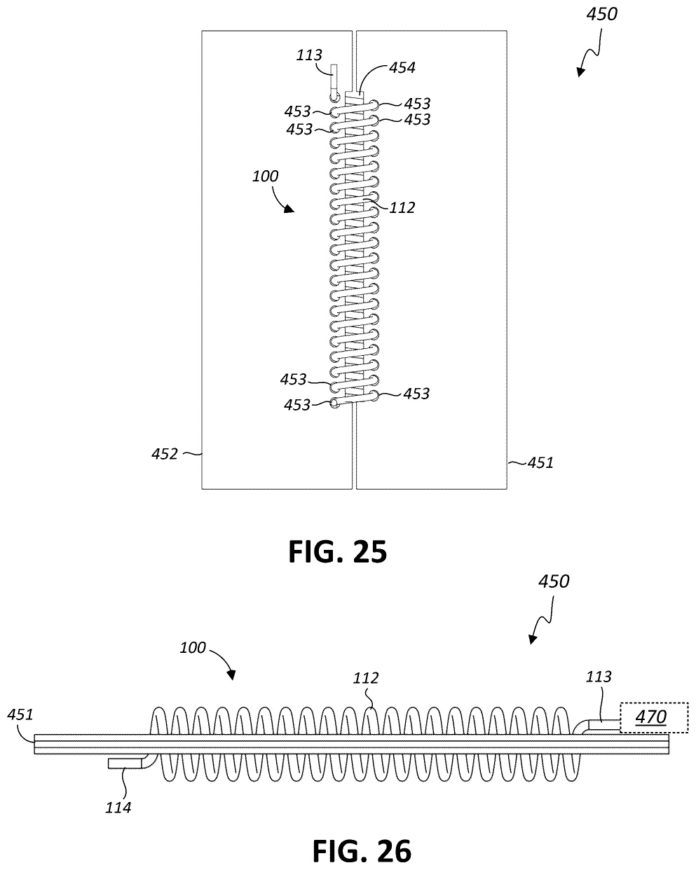

FIG. 25 shows a top view of the electronic assembly 450, in accordance with an embodiment of the present invention. FIG. 25 provides another view of the channel 454 within the spiral inductor 100. The wire 112 of the spiral inductor 100 spirals through the substrates 451 and 452 by way of the through holes 453, which are along the side edges that have the edge cutouts.

FIG. 26 shows a side view of the electronic assembly 450, in accordance with an embodiment of the present invention. FIG. 26 shows a schematic representation of an electrical circuit 470, which comprises a plurality of electronic components (e.g., resistors, capacitors, other inductors, IC chips) that are electrically connected to the spiral inductor 100. The electrical circuit 470 may be mounted on an outermost surface of the substrate 451 or the substrate 452, and may be electrically connected to the first end 113 of the wire 112 as shown, to the second end 114, or to both the first end 113 and the second end 114. The first end 113 and the second end 114 may be on opposite sides of a plane formed by the substrates 451 and 452 as shown or on the same side of the plane.

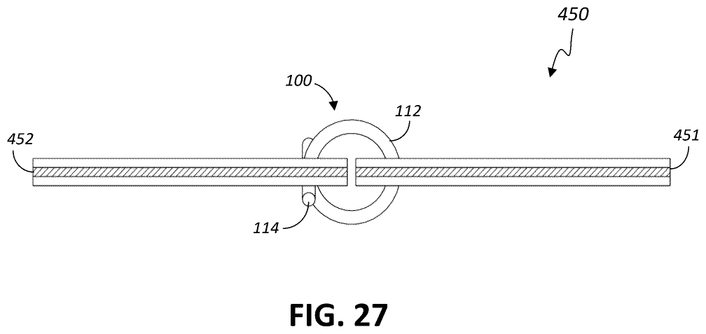

FIG. 27 shows a front view of the electronic assembly 450, in accordance with an embodiment of the present invention. The substrates 451 and 452 are shown with the second end 114 of the wire 112 of the spiral inductor 100 facing the viewer for reference.

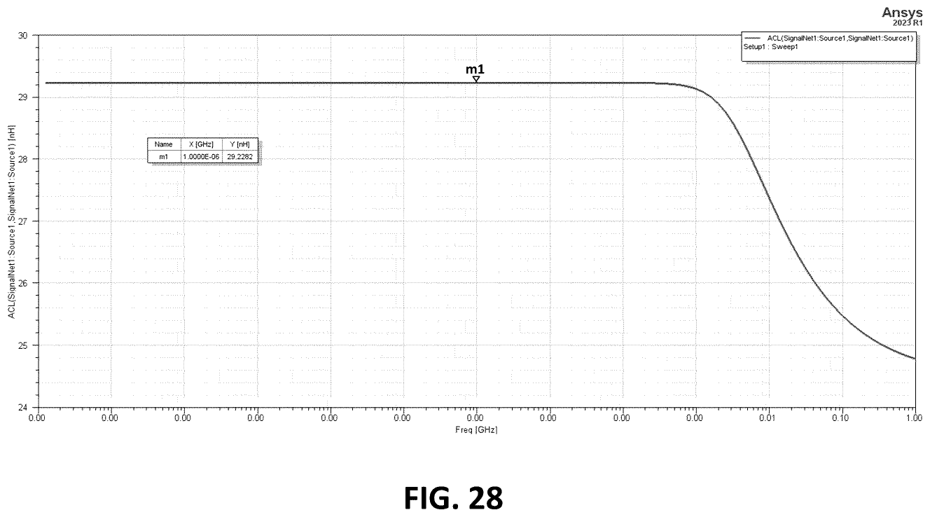

FIG. 28 shows a plot of inductance versus frequency of a simulation of the spiral inductor 100 in the electronic assembly 450, in accordance with an embodiment of the present invention. The simulation was performed using the ANSYS 2023 R1 simulation software. In the simulation of FIG. 28, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils. Each of the substrates 451 and 452 is a conventional PCB, which does not appreciably affect the inductance of the spiral inductor 100. In the example of FIG. 28, the vertical axis represents inductance in nH and the horizontal axis represents frequency in gHz. For reference, at the point m1 in FIG. 28, the spiral inductor 100 in the simulation has an inductance of around 29.2 nH at around 1 kHz.

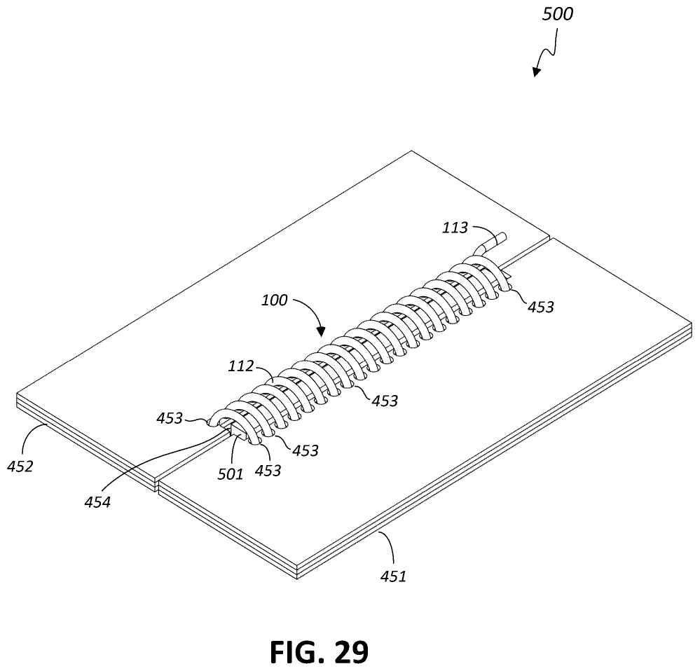

FIG. 29 shows a perspective view of an electronic assembly 500, in accordance with an embodiment of the present invention. The electronic assembly 500 is essentially the same as the electronic assembly 450 (shown in FIGS. 24-27) except for the addition of a magnetic core 501 that is disposed within the spiral inductor 100. That is, whereas the spiral inductor 100 has an air core in the electronic assembly 450, the spiral inductor 100 has a magnetic core 501 in the electronic assembly 500. The magnetic core 501 is disposed in the channel 454 formed by edge cutouts on side edges of the substrates 451 and 452. The wire 112 is wound a plurality of turns, in spiral fashion, around the magnetic core 501 and the side edges of the substrates 451 and 452 by way of corresponding through holes 453. The electronic assemblies 450 and 500 are otherwise essentially the same.

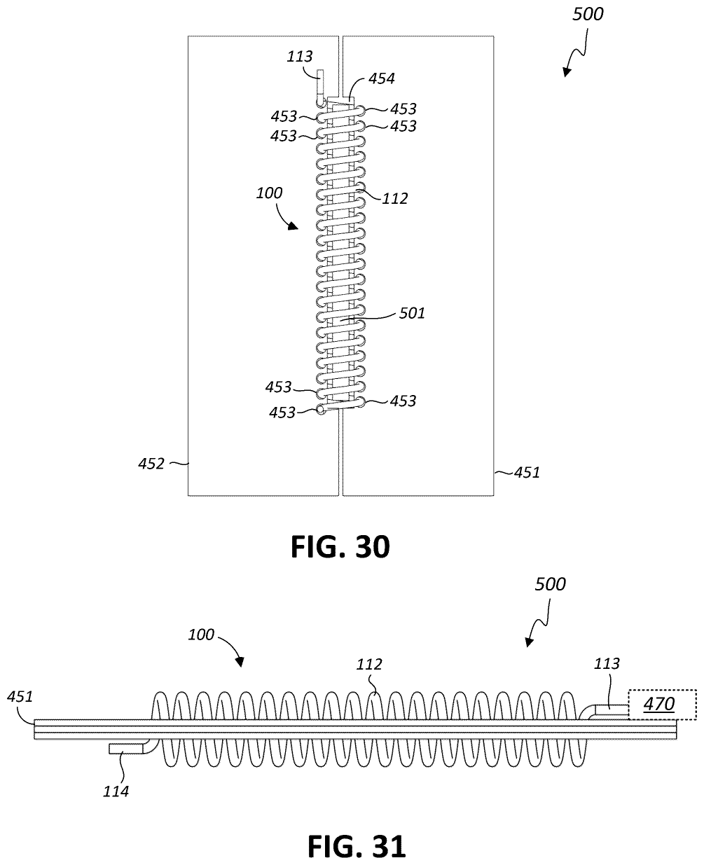

FIGS. 30 and 31 show a top view and a side view, respectively, of the electronic assembly 500, in accordance with an embodiment of the present invention. The magnetic core 501 may comprise a magnetic material commonly used in inductors, such as iron powder and ferrites. The magnetic core 501 may be disposed within the spiral inductor 100 by form fitting the magnetic core 501 into the inside diameter of the spiral inductor 100 or some other way depending on implementation particulars. The magnetic core 501 may have a rectangular box shape as shown, cylindrical shape, two-half cylindrical shapes, or other shape. Changing the shape, size, and/or material of the magnetic core 501 allows for adjustment of the inductance of the spiral inductor 100 in the electronic assembly 500.

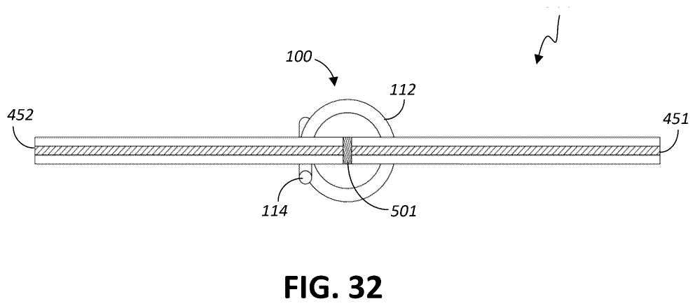

FIG. 32 shows a front view of the electronic assembly 500, in accordance with an embodiment of the present invention. The substrates 451 and 452 are shown with the second end 114 of the wire 112 of the spiral inductor 100 facing toward the viewer for reference.

The numbered components of the electronic assembly 500 in FIGS. 29-32, except for the magnetic core 501, are as described in previous figures with the same reference numbers.

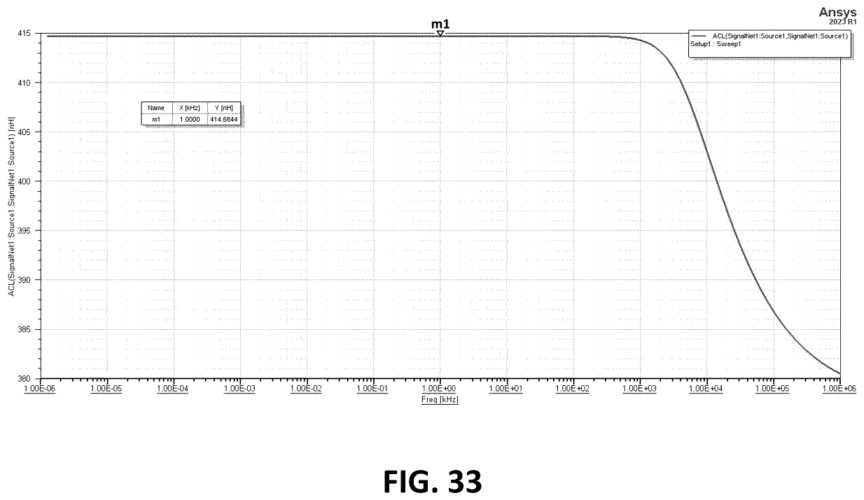

FIG. 33 shows a plot of inductance versus frequency from a simulation of the spiral inductor 100 in the electronic assembly 500, in accordance with an embodiment of the present invention. The simulation was performed using the ANSYS 2023 R1 simulation software. In the simulation of FIG. 33, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils; and the magnetic core 501 is a ferrite core. Each of the substrates 451 and 452 is a conventional PCB, which does not appreciably affect the inductance of the spiral inductor 100. In FIG. 33, the vertical axis represents inductance in nH and the horizontal axis represents frequency in kHz. For reference, at the point m1 in FIG. 33, the spiral inductor 100 in the simulation has an inductance of around 414.68 nH at around 1 kHz. The increased inductance relative to the spiral inductor 100 in the electronic assembly 450 (see FIG. 28) is attributed to the addition of the magnetic core 501 in the spiral inductor 100.

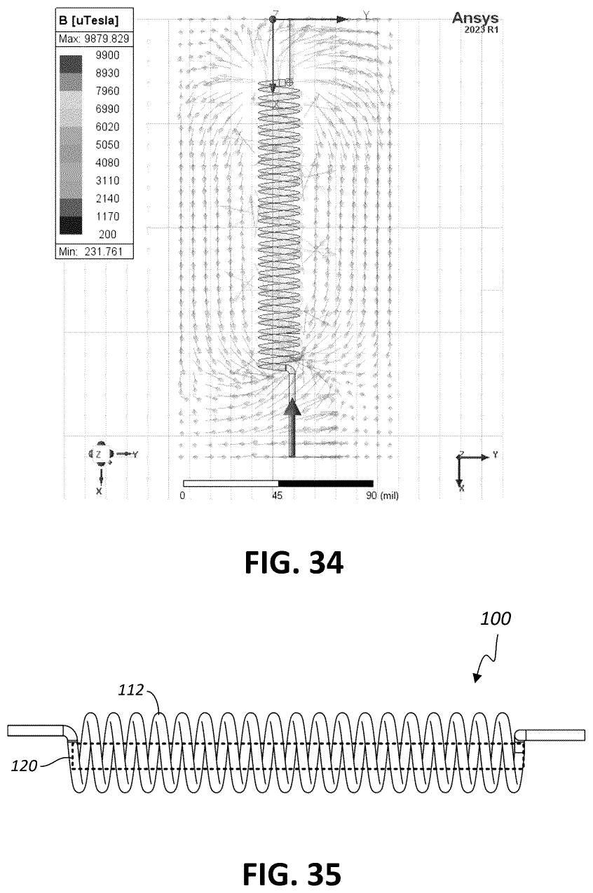

FIG. 34 shows a magnetic field simulation of the spiral inductor 100, in accordance with an embodiment of the present invention. The simulation was performed using the ANSYS 2023 R1 simulation software. In the simulation of FIG. 34, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils. There is no PCB with the spiral inductor 100 in the simulation of FIG. 34. The simulation indicates that magnetic flux density from about 231.76 micro Tesla to about 9879.83 micro Tesla can be generated by the spiral inductor 100.

FIG. 35 shows a side view of the spiral inductor 100 with a magnetic core 120, in accordance with an embodiment of the present invention. The spiral inductor 100 in FIG. 35 is the same as in FIGS. 1-3 except for the addition of the magnetic core 120, which is schematically illustrated as a dotted rectangular box. The magnetic core 120 is disposed within the spiral wound portion of the spiral inductor 100.

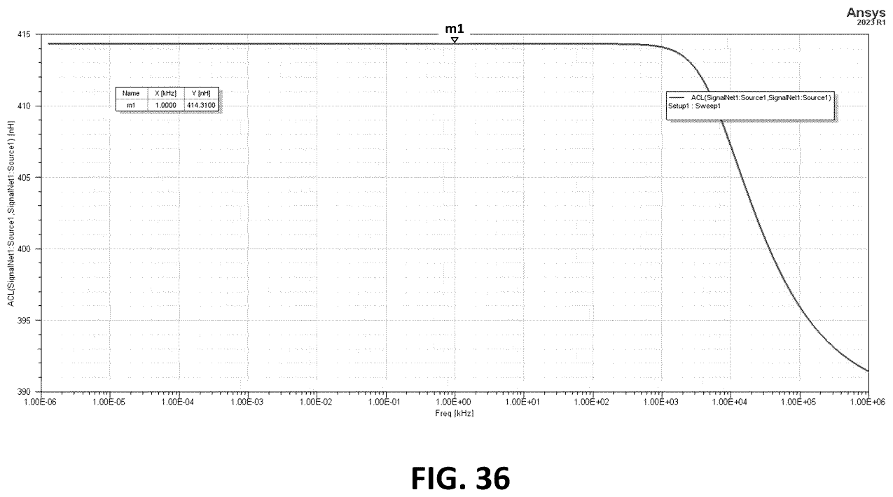

FIG. 36 shows a plot of inductance versus frequency of a simulation of the spiral inductor 100 of FIG. 35, in accordance with an embodiment of the present invention. The simulation was performed using the ANSYS 2023 R1 simulation software. In the simulation of FIG. 36, the wire 112 is a copper wire with a wire diameter of 3 mils; the spiral inductor 100 has a spiral wound portion with a length (see FIG. 2, length L) of 146 mils and an inside diameter (see FIG. 3, inside diameter D) of 20 mils; and the magnetic core 120 is a ferrite core. There is no PCB with the spiral inductor 100 in the simulation of FIG. 36. In FIG. 36, the vertical axis represents inductance in nH and the horizontal axis represents frequency in kHz. For reference, at the point m1 in FIG. 36, the spiral inductor 100 in the simulation has an inductance of around 414.3 nH at around 1 kHz.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. An electronic assembly comprising:
a first substrate comprising a plurality of through holes that each goes through the first substrate, the plurality of through holes of the first substrate is disposed along a side edge of the first substrate;
an inductor comprising a wire that is wound in spiral fashion around the side edge of the first substrate a plurality of turns by way of the plurality of through holes of the first substrate; and
an electrical circuit that is electrically connected to the inductor.

2. The electronic assembly of claim 1, wherein the first substrate is a printed circuit board, and the electrical circuit is mounted on the printed circuit board.

3. The electronic assembly of claim 1, further comprising:
a magnetic core disposed within the inductor.

4. The electronic assembly of claim 3, wherein the magnetic core is disposed within a cutout that is cut on the side edge of the first substrate.

5. The electronic assembly of claim 1, wherein the inductor serves as an antenna of the electrical circuit.

6. The electronic assembly of claim 1, further comprising:
a second substrate that comprises a plurality of through holes that each goes through the second substrate, the plurality of through holes of the second substrate is disposed along a side edge of the second substrate,
wherein the wire is wound in spiral fashion a plurality of turns around the side edge of the first substrate and the side edge of the second substrate.

7. The electronic assembly of claim 6, further comprising a magnetic core that is disposed within the inductor.

8. The electronic assembly of claim 6, further comprising an electrical insulator layer that is disposed between the first substrate and the second substrate.

9. The electronic assembly of claim 6, wherein the first substrate and the second substrate are disposed side-by-side.

10. The electronic assembly of claim 6, wherein the first substrate and the second substrate are stacked.

11. An electronic assembly comprising:
a first substrate having a plurality of through holes that each goes through the first substrate, the plurality of through holes of the first substrate being disposed along a side edge of the first substrate;
a second substrate having a plurality of through holes that each goes through the second substrate, the plurality of through holes of the second substrate being disposed along a side edge of the second substrate; and
an inductor comprising a wire that is wound in spiral fashion a plurality of turns around the side edge of the first substrate and the side edge of the second substrate by way of the plurality of through holes of the first substrate and the plurality of through holes of the second substrate.

12. The electronic assembly of claim 11, further comprising:
a magnetic core that is disposed within the inductor.

13. The electronic assembly of claim 12, wherein the magnetic core is disposed in a cutout on the side edge of the first substrate and in a cutout on the side edge of the second substrate.

14. The electronic assembly of claim 11, further comprising:
an electrical insulator between the first substrate and the second substrate.

15. The electronic assembly of claim 11, wherein the first substrate and the second substrate are disposed side-by-side.

16. The electronic assembly of claim 15, further comprising a magnetic core that is disposed in a channel formed by cutouts on the side edge of the first substrate and the side edge of the second substrate;

17. The electronic assembly of claim 11, wherein the first substrate and the second substrate are stacked.

18. The electronic assembly of claim 11, wherein the inductor serves as an antenna of an electrical circuit of the electronic assembly.
